(19) United States
(12) Patent Application Publication
(10) Pub. No.: US 2013/0095243 A1
(43) Pub. Date: Apr. 18, 2013

(54) METAL TITANIUM PRODUCTION DEVICE AND METAL TITANIUM PRODUCTION METHOD

(71) Applicants: Gang Han, Yasugi-shi (JP); Tatsuya Shoji, Yasugi-shi (JP); Shujiroh Uesaka, Yasugi-shi (JP); Mariko Fukumaru (Abe), Yasugi-shi (JP); Maher I. Boulos, Sherbrooke (CA); Jiayin Guo, Sherbrooke (CA); Jerzy Jurewicz, Sherbrooke (CA)

(72) Inventors: Gang Han, Yasugi-shi (JP); Tatsuya Shoji, Yasugi-shi (JP); Shujiroh Uesaka, Yasugi-shi (JP); Mariko Fukumaru (Abe), Yasugi-shi (JP); Maher I. Boulos, Sherbrooke (CA); Jiayin Guo, Sherbrooke (CA); Jerzy Jurewicz, Sherbrooke (CA)

(73) Assignees: TEKNA PLASMA SYSTEMS INC., Sherbrooke, Quebec (CA); HITACHI METALS, LTD., Minato-ku, Tokyo (JP)

(21) Appl. No.: 13/639,358

(22) PCT Filed: Mar. 7, 2011
(86) PCT No.: PCT/JP2011/055184

§ 371 Date: Dec. 21, 2012

(30) Foreign Application Priority Data
Apr. 7, 2010 (JP) 2010-088568

(51) Int. Cl. C23C 16/06

(52) U.S. Cl. CPC C23C 16/06
USPC 427/250; 118/726; 118/723 E; 118/724

(57) ABSTRACT

A metal titanium production device comprising: (a) a magnesium evaporation unit in which solid magnesium is evaporated and a first flow path which is communicated with the evaporation unit and through which gaseous magnesium is supplied; (b) a second flow path through which gaseous titanium tetrachloride is supplied; (c) a gas mixing unit which is communicated with the first flow path and the second flow path and in which the gaseous magnesium is mixed with titanium tetrachloride, the absolute pressure is adjusted to 50 to 500 kPa and the temperature is adjusted to 1600° C. or higher; (d) a metal titanium precipitation unit which is communicated with the gas mixing unit and in which a precipitation substrate having at least partially a temperature of 715 to 1500° C. is placed and the absolute pressure is adjusted to 50 to 500 kPa; and (e) a mixed gas discharge unit which is communicated with the metal titanium precipitation unit.

### TECHNICAL FIELD

The present invention generally relates to a process and an apparatus for producing titanium metal. More specifically, the invention relates to a process and apparatus for producing titanium metal by making titanium metal deposited and grown from a mixed gas of titanium tetrachloride and magnesium.

### BACKGROUND ART

Titanium is a light metal having a high mechanical strength to weight ratio and exhibiting superior corrosion resistance. Titanium is widely used in various fields including airplane, medical and automobile industries. An amount of titanium in used has been increasing. Titanium is the fourth most abundant element in the earth's crust after aluminum, iron and magnesium among metal elements and thus is a plentiful resource. However, titanium is up against short supply and has been at least an order of magnitude more expensive than steel materials.

Currently, titanium metal has been mainly produced by a Kroll Process. In the Kroll Process, titanium ore, the main component of which is titanium dioxide (TiO₂), is reacted with a chlorine gas and coke (C) to provide titanium tetrachloride (TiCl₄). Subsequently, highly-purified titanium tetrachloride is produced through distillation and separation. Titanium metal is produced through thermal reduction of the purified titanium tetrachloride by magnesium (Mg). In a thermal reduction step of the Kroll Process, a reduction reaction vessel made of stainless steel is filled with a magnesium melt at a temperature of not lower than 800° C. Titanium tetrachloride in a liquid phase is dropped into the vessel from above and reacts with the magnesium melt in the vessel to produce titanium. The produced titanium sinks in the magnesium melt and thus titanium metal is produced in a sponge form. By-product magnesium chloride and unreacted magnesium in the liquid phase are mixed in the titanium metal in the sponge form. Upon completion of the reaction, the mixture is subjected to a vacuum separation process at a high temperature of not lower than 1000° C. to obtain a sponge cake of porous titanium metal. The sponge cake is cut and crushed to produce sponge titanium.

The Kroll Process can be effective to produce a titanium material for practical use. However, a long production time is required since the thermal reduction process and the separation process are conducted separately. Since it is a batch process, the production is less efficient. Accordingly, various techniques have been suggested to overcome the problems of the Kroll Process.

For example, Patent Literature 1 (JP-B-33-3004) discloses a process for collecting titanium, which includes steps of supplying a titanium tetrachloride gas and magnesium vapor in a reaction vessel to cause a gas-phase reaction under a temperature range of 800 to 1100° C. and a vacuumed atmosphere of 10⁻⁴ mmHg (1.3×10⁻² Pa) in the vessel, and depositing titanium metal on a net-like collection material disposed in the vessel

Patent Literature 2 (U.S. Pat. No. 2,997,385) discloses a process for producing metal, which includes a step of introducing halide vapor as a metal element and alkali metal or alkaline earth metal vapor as a reducing agent into a reaction vessel to cause a gas-phase reaction in the vessel in an evacuated atmosphere under a temperature range of 750 to 1200° C. and a pressure of 0.01 to 300 mmHg (1.3 Pa to 40 kPa).

Example II in Patent Literature 2 discloses that titanium metal was produced from TiCl₄ gas and Mg gas. Specifically, the reaction was caused under a reaction temperature of approximately 850° C. and a pressure of 10 to 200 microns (1.3 to 26.7 Pa).

Non Patent Literature 1 (D. A. Hansen and S. J. Gerdemann, JOM, 1998, No. 11, page 56) discloses a process for producing titanium ultrafine powders through a gas-phase reaction. According to the process, titanium tetrachloride gas and magnesium gas are introduced into a reaction vessel and reacted at a temperature of not lower than 850° C., and produced titanium ultrafine powders and concomitantly produced MgCl₂ powders are separated in a cyclone at a lower portion. Then, magnesium and MgCl₂ are separated from the obtained titanium ultrafine powders through vacuum distillation or filtration.

### CITATION LIST

### Patent Literature

Patent Literature 1: JP-B-33-3004

Patent Literature 2: U.S. Pat. No. 2,997,385

Patent Literature 3: JP-A-2009-242946

### Non Patent Literature

Non Patent Literature 1: D. A. Hansen and S. J. Gerdemann, JOM, 1998, No. 11, page 56

### DISCLOSURE OF THE INVENTION

According to searches by the inventors, a small amount of titanium can be collected by the process disclosed in Patent Literature 1. However, supply rate of reactants is required to be limited in order to maintain a pressure to 10⁻⁴ mmHg in a reaction vessel. Production capacity may be increased by increasing a size of a vacuum pump and exhaust capability. However, it is difficult to obtain a large amount of titanium metal for industrial use.

By the process disclosed in Patent Literature 2, purified titanium can be collected as well as by the process disclosed in Patent Literature 1. However, a production rate is low at a low-pressure.

Powder produced by the process disclosed in Non Patent Literature 1 has an approximately submicron size and thus magnesium and MgCl₂ can not be efficiently separated from the powder. Accordingly, a large amount of impurities are contained. Thus, the process requires an independent means for separation, such as vacuum distillation.

As described above, the literatures suggest processes for producing titanium through a gas-phase reaction of titanium tetrachloride gas with magnesium gas in order to overcome the problems of the Kroll Process. However, it is essentially required to separate by-product MgCl₂ or unreacted magnesium in a highly evacuated state according to these processes, and thus it is difficult to obtain a large amount of titanium.

The inventors have proposed a process and an apparatus for depositing titanium metal by supplying titanium tetrachloride and magnesium into RF thermal plasma flame. Titanium tetrachloride and magnesium evaporate in the RF thermal plasma flame and titanium tetrachloride is reduced by magnesium, thereby reduced titanium metal deposits (JP-A-2009-242946).

According to the process, uniform mixing of a titanium tetrachloride gas and magnesium gas is essential for efficient reaction of the gases.

An object of the invention is to provide a process for effectively producing titanium metal from titanium tetrachloride and magnesium as starting materials.

An apparatus for producing titanium metal according to the invention includes: (a) a magnesium evaporation unit for evaporating solid magnesium and a first flow path connected to the magnesium evaporation unit and for supplying gaseous magnesium; (b) a second flow path supplying gaseous titanium tetrachloride; (c) a gas mixing unit in communication with the first flow path and the second flow path, wherein the gaseous magnesium is mixed with the titanium tetrachloride in the gas mixing unit, and the gas mixing unit is controlled to have 50 to 500 kPa and an absolute pressure of not lower than 1600° C. therein; (d) a titanium metal precipitation unit in communication with the gas mixing unit, wherein the titanium metal precipitation unit includes a precipitation substrate arranged therein, at least a part of the precipitation substrate being in a temperature range from 715 to 1500° C., an absolute pressure in the titanium metal precipitation unit being 50 to 500 kPa; and (e) a mixed gas discharge unit in communication with the titanium metal precipitation unit.

Preferably, the solid magnesium evaporation unit may include a DC plasma torch as a thermal source for evaporation.

Preferably, the absolute pressure in the titanium metal precipitation unit may be 90 to 200 kPa.

Preferably, at least one of the first flow path, the second flow path, the gas mixing unit, and the titanium metal precipitation unit may have a graphite wall. More preferably, a part or whole of the graphite wall may be heated through induction-heating.

Preferably, the precipitation substrate may be in a roll shape having raised and recessed sections of different diameters in a direction perpendicular to a rotation axis. The precipitation substrate may be rotatable about a central axis. Additionally, the precipitation substrate may include a scraper for scraping away titanium metal deposited on a surface of the precipitation substrate.

Preferably, at least a part of the precipitation substrate may be in a temperature range from 900 to 1200° C.

Preferably, the precipitation substrate may be made of titanium or a titanium alloy.

Further, a process for producing titanium metal according to the invention includes steps of: (a) evaporating solid magnesium; (b) supplying gaseous magnesium evaporated in the step (a) and gaseous titanium tetrachloride into a mixing space at an absolute pressure of 50 to 500 kPa and at a temperature of not lower than 1600° C. to form a mixed gas; (c) introducing the mixed gas into a precipitation space, wherein the precipitation space has an absolute pressure of 50 to 500 kPa, the precipitation space includes a precipitation substrate arranged therein, and at least a part of the precipitation substrate is in a temperature range from 715 to 1500° C.; (d) depositing and growing titanium metal on the precipitation substrate; and (e) discharging the mixed gas after the step (d).

According to the apparatus and the process for producing titanium metal, titanium can be directly produced by a gas-phase reaction between titanium tetrachloride and magnesium. Thus, high pure titanium can be produced with a high productivity. Additionally, since titanium is deposited on the precipitation substrate, additional steps are not necessary to separate by-products, such as titanium tetrachloride and unreacted magnesium. Furthermore, continuous production may be achieved by drawing out the precipitation substrate depending on growth rate of the titanium metal.

The above-described object and other objects, advantages, and features will be apparent from non-restrictive embodiments as described below with reference to accompanying drawings.

### BRIEF DESCRIPTION OF DRAWINGS

FIG. 1 is a schematic sectional side view of an example of an apparatus for producing titanium metal.

FIG. 2 is a schematic sectional side view of an example of a magnesium evaporation unit.

FIG. 3 is a schematic sectional side view of an example of titanium metal precipitation unit.

FIG. 4 is a schematic view of a precipitation substrate and a scraper of the titanium metal precipitation unit.

### DESCRIPTION OF EMBODIMENTS

The invention discloses a new apparatus and a process for producing titanium metal.

According to the invention, magnesium gas is evaporated from magnesium which is a solid at room temperature. The gaseous magnesium and gaseous titanium tetrachloride are supplied into a mixing space at an absolute pressure of 50 to 500 kPa and at a temperature of not lower than 1600° C. to form a mixed gas. Since the mixed gas is formed in advance by mixing titanium tetrachloride gas with magnesium gas which has been evaporated into a gaseous state, continuous and uniform reaction can be carried out in a reaction vessel. Since a driving force for generating the reaction between titanium tetrachloride and magnesium decreases depending on increase of temperature, the reaction can be substantially suppressed at a temperature of not lower than 1600° C. and therefore only mixing of the reactant gases can be performed. One important feature of the invention is the formation of a uniform mixed gas of titanium tetrachloride and magnesium.

Next, the mixed gas is introduced into a titanium metal precipitation space. The titanium metal precipitation space has an absolute pressure of 50 to 500 kPa. A precipitation substrate is arranged in the titanium metal precipitation space, and at least a part of the precipitation substrate is controlled at a temperature from 715 to 1500° C. A driving force for the reaction of generating titanium is increased as the temperature of the mixed gas decreases.

A surface of the precipitation substrate arranged in the titanium metal precipitation space promotes heterogeneous nucleation and promotes generation and deposition of titanium.

Another important feature of the invention is that the absolute pressure of the titanium metal precipitation space is 50 to 500 kPa. Lower pressure in the titanium metal precipitation space is advantageous for evaporation and separation of magnesium and MgCl₂. Even when the reaction occurs ununiformly, by-products or intermediate compounds can be evaporated and separated since vacuum depressurization facilitates the evaporation. In fact, Kroll Process produces titanium by forming a mixture of titanium, magnesium and MgCl₂ in a liquid phase and then performing vacuum separation under a pressure of 0.1 to 1 Pa and at a temperature of 1000° C.

However, the process of the invention employs the absolute pressure of 50 to 500 kPa that is almost the same as atmospheric pressure. According to the prior art literatures, magnesium and MgCl₂ can not be separated from titanium under such a pressure. The inventors have found that titanium is crystallized and grown on the precipitation substrate even under such a pressure that is not traditionally used, and surprisingly, the deposited titanium has high purity.

In general, treatment capability per unit reactor volume is increased with an increase of a pressure in a reactor. For example, when the pressure is increased by one order of magnitude, treatment capability is increased by one order of magnitude. According to the invention, treatment capability can be remarkably improved since such a pressure can be applied as has not been used hitherto.

Although titanium can be collected in principle even under a pressure of less than 50 kPa, production rate is reduced as the pressure decreases, and possibility of air leakage into an apparatus is increased. Since titanium has high reactive activity with oxygen and nitrogen, it is required to protect the production process from outer air. As a degree of vacuum is increased, cost for preventing the air leakage into the apparatus during the process is increased. Under a pressure of not lower than 50 kPa, the air leakage can be easily prevented at an industrial production level. Thus, the pressure range of not lower than 50 kPa is preferable for practical use.

Although treatment capability per unit reactor volume is increased with increase of a pressure, evaporation efficiency of MgCl₂ is reduced. Therefore, when the pressure exceeds 500 kPa, it becomes difficult to produce highly-purified titanium. In addition, production cost is increased to deal with high pressure in industrial equipment. Thus, pressure of not greater than 500 kPa is effective.

In view of treatment capability, separation efficiency, and economic rationality of industrial equipment, a preferable range of absolute pressure is 90 to 200 kPa.

In a temperature range of 715 to 1500° C., titanium can be deposited as particles on a surface of a precipitation substrate under a pressure of 50 to 500 kPa. As a temperature is decreased, a driving force for generating the reaction is increased and evaporation efficiency of magnesium and MgCl₂ is reduced. On the contrary, as a temperature is increased, MgCl₂ and the like are efficiently evaporated and the driving force is reduced. At a temperature of not lower than 1500° C., reduction reaction of titanium does not easily proceed. At a temperature of not higher than 715° C., homogeneous nucleation of reaction gas occurs and titanium is not easily deposited on the surface of the precipitation substrate. Accordingly, the temperature of at least a part of the substrate is preferably in a range of 715 to 1500° C.

In view of stable titanium deposition at a lower temperature as well as a selection of structural material for a reaction vessel, operation at a lower temperature is desirable.

However, reaction products such as MgCl₂ may be possibly mixed at a lower temperature. Accordingly, a temperature range is preferably 900 to 1300° C., more preferably 900 to 1200° C., to realize stable industrial production.

In the invention, the precipitation substrate is arranged in the titanium metal precipitation space to ensure a contact area with the mixed gas. The precipitation substrate arranged in the titanium metal precipitation space serves as a precipitation site for introduced mixed gas and titanium metal can be deposited and grown on the substrate.

A surface of the precipitation substrate provides a place for heterogeneous nucleation of titanium produced by the reaction and promotes its deposition. The precipitation substrate desirably has a shape that allows the mixed gas to pass through uniformly without loss and contact the substrate. Therefore, it is desirable that the precipitation substrate has a space therein with a large surface area so that the mixed gas sufficiently flow therethrough. A porous structure is preferable in order to ensure a surface area ratio of the precipitation substrate. It is also preferable that the precipitation substrate has a shape extending in a direction where the mixed gas flows and forms a flow path of the mixed gas.

It is desirable to provide a mechanism for scraping the precipitation substrate depending on deposition and growth rate of the titanium metal in order to collect the deposited titanium metal continuously. Since the inventors observed that a large amount of titanium metal is deposited at a tip of the precipitation substrate, that is an end surface facing a flow of the mixed gas. Thus, when the deposited titanium is scraped away, the titanium deposited on the end surface can be continuously grown.

A scraper function may be added in order to scrape away the titanium on the surface of the precipitation substrate or a plurality of precipitation substrates may be provided, whose precipitation portions are slid on each other to scrape away the deposited titanium. Alternatively, vibration may be applied to the precipitation substrate to continuously collect the titanium particles on the surface of the precipitation substrate.

Furthermore, the precipitation substrate may be cooled in order to take off a reaction heat for controlling a temperature of the reaction.

Material for the precipitation substrate is not particularly limited in the invention. For example, ceramic or metal may be used. A refractory metal, which does not melt or change its properties in a temperature range of 700 to 1500° C., is desirable since the precipitation substrate is controlled in the temperature range. For effective deposition, the material preferably has a crystalline structure similar to that of titanium. In particular, pure titanium or a titanium alloy is preferable as the material.

Pure titanium is particularly desirable for the precipitation substrate in order to maintain a degree of purity of collected titanium and prevent mixing of impurities.

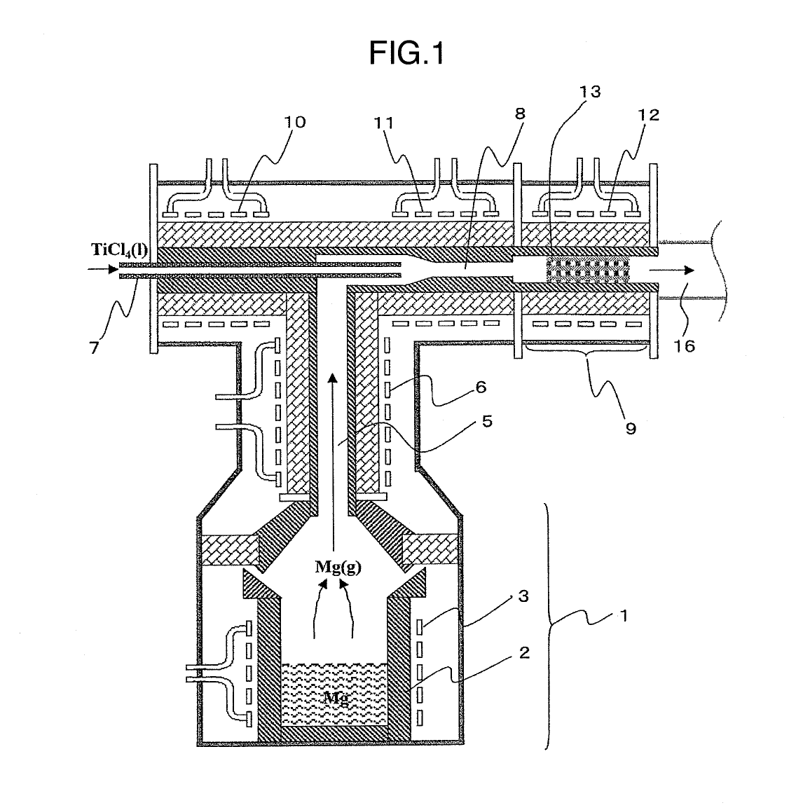

FIG. 1 shows a schematic sectional side view of an example of titanium metal production apparatus according to the invention. The apparatus includes: a magnesium evaporation unit 1 that has a mechanism for evaporating solid magnesium: a first flow path 5 in communication with the evaporation unit and supplying gaseous magnesium; a second flow path 7 supplying gaseous titanium tetrachloride; a gas mixing unit 8 in communication with the first flow path and the second flow path, in which the gaseous magnesium is mixed with the titanium tetrachloride; a titanium metal precipitation unit 9 in communication with the gas mixing unit; and a mixed gas discharge unit 16 in communication with the titanium metal precipitation unit.

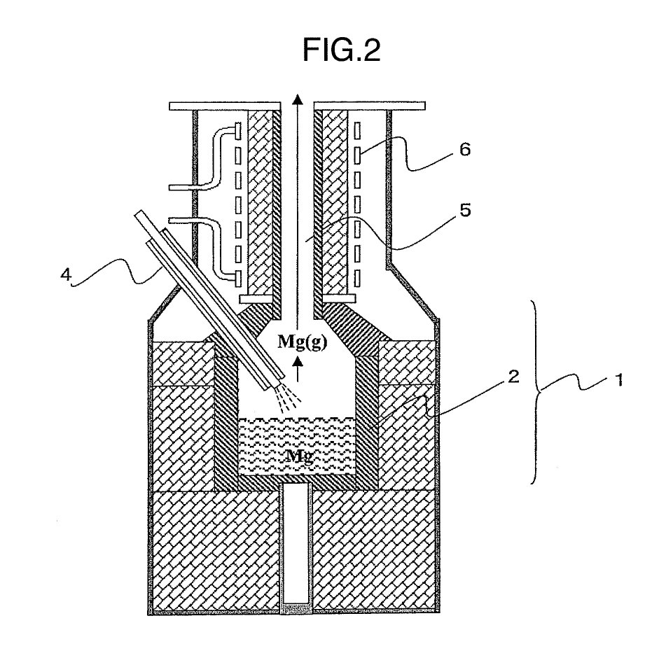

The evaporation unit 1 includes a crucible 2 in which solid magnesium is placed and a thermal source for evaporating the solid magnesium. As an example of the thermal source for the evaporation, FIG. 1 shows heaters 3 located around at least a part of a side wall of the crucible 2. The heaters raise a temperature within the crucible to a magnesium evaporation temperature to evaporate the solid magnesium. Other example of the thermal source is to induction-heat the graphite wall with use of a heater outside the crucible. Still other example of the thermal source is a DC plasma torch 4 as shown in the schematic sectional side view of the evaporation unit of FIG. 2. Since the DC plasma torch, if applied, can locally heat a liquid surface of magnesium with a plasma arc, the DC plasma torch is effective to control an evaporation rate of magnesium and is advantageous in stably evaporating magnesium.

The first flow path 5 for supplying gaseous magnesium to the gas mixing unit 8 is connected to the magnesium evaporation unit 1. According to an embodiment of the invention, heaters 6 may be positioned around at least a part of a side wall of the first flow path 5. The heaters raise a temperature within the flow path to a temperature at which magnesium evaporates so as to prevent magnesium from depositing in the flow path. As an alternative embodiment, a heater with coils provided outside the flow path may be used to heat the graphite wall of the flow path through induction-heating.

The titanium production apparatus according to the invention includes the second flow path 7 for supplying gaseous titanium tetrachloride to the gas mixing unit 8.

According to an embodiment of the invention, heaters 10 may be provided around at least a part of a side wall of the second flow path 7. The heaters raise a temperature within the second flow path to a predetermined temperature. The second flow path 7 may be formed of a material having corrosion resistance against a chloride vapor. For example, the corrosion resistant material may be graphite. As an alternative embodiment, the second flow path 7 may be heated with a heater with coils. The second flow path 7 may be heated through induction-heating of the graphite wall of the second flow path 7.

The gas mixing unit 8 is connected to the first flow path 5 for supplying gaseous magnesium and the second flow path 7 for supplying gaseous titanium tetrachloride, and is controlled to have an absolute pressure of 50 to 500 kPa and a temperature of 1600° C. or higher. This is because reduction reaction of titanium tetrachloride and magnesium can not be caused as long as the absolute pressure and the temperature are maintained to these levels. Heaters 11 may be provided around at least a part of a side wall of the gas mixing unit to control the gas mixing unit in the above temperature range. An inner wall of the gas mixing unit may desirably be formed of a material having corrosion resistance against a chloride vapor and an example of the corrosion resistant material may be graphite. According to an embodiment of the invention, temperature control can be achieved by a heater with coils provided on an outside of the side wall of the gas mixing unit to heat the wall through induction-heating.

The titanium metal precipitation unit 9 connected to the gas mixing unit 8 is maintained at an absolute pressure of 50 to 500 kPa, and is provided with a precipitation substrate 13 arranged therein, at least a part of which is in a temperature range from 715 to 1500° C. At least a part of the precipitation substrate is preferably controlled in a temperature range from 900 to 1200° C. The mixed gas of titanium tetrachloride and magnesium causes a reduction reaction of titanium tetrachloride by magnesium at the temperature. Produced titanium is then deposited and grown on a surface of the precipitation substrate. Heaters 12 may be provided around at least a part of a side wall of the precipitation unit. The heaters raise a temperature within the titanium metal precipitation unit to a predetermined temperature to control the precipitation substrate to have the above temperature. An inner wall of the titanium metal precipitation unit may desirably be formed of a material having corrosion resistance against a chloride vapor and an example of the corrosion resistant material may be graphite. As an alternative embodiment, temperature control can be achieved by a heater with coils provided on an outside of the side wall of the titanium metal precipitation unit to heat the wall through induction-heating.

It is desirable that the precipitation substrate has a shape configured to allow the mixed gas to pass through uniformly and contact the precipitation substrate while securing a flow path for the mixed gas to sufficiently flow therethrough and that ensure a large surface area which contributes to deposition.

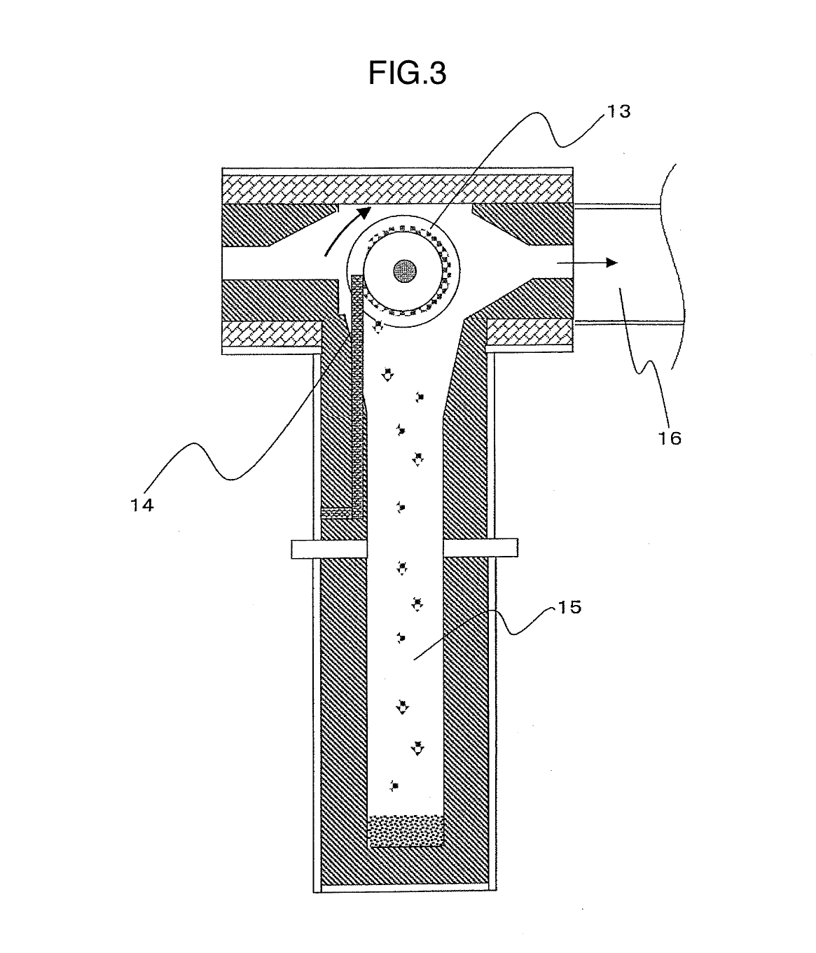

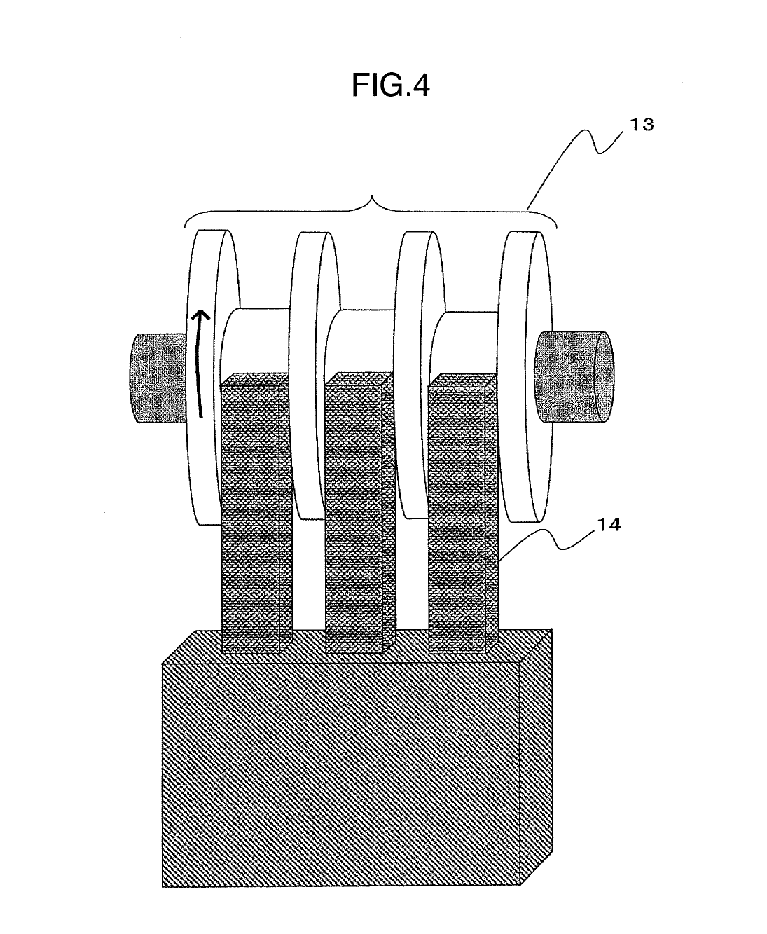

One embodiment of a mechanism for continuously collecting titanium metal deposited on the precipitation substrate is to provide a precipitation substrate 13 having a roll shape and having raised and recessed sections of different diameters in a direction perpendicular to a rotation axis, and to rotate a central axis with a motor, as shown in a schematic sectional side view of a titanium metal precipitation unit of FIG. 3 or in a schematic drawing of a precipitation substrate and a scraper of the titanium metal precipitation unit of FIG. 4. An example of this arrangement is, but not limited to, a plurality of disk shaped metal plates connected together on a same central axis. Under the roll-shaped precipitation substrate 13, is provided a scraper 14 for scraping away titanium metal deposited on a surface of the precipitation substrate. Scraped titanium may be continuously collected by a collector 15 connected to the bottom of the titanium metal precipitation unit.

A mixed gas of gaseous magnesium and gaseous titanium tetrachloride except for titanium deposited and grown in the titanium metal precipitation unit 9, along with by-product magnesium chloride, is discharged to a discharge unit connected to the precipitation unit and is collected by a filter or the like.

### Example 1

An example will be explained hereinbelow for exemplifying efficiency of the process for producing titanium metal according to the invention. An apparatus used in the experiment has a base structure in FIG. 1. A magnesium evaporation unit has a structure in FIG. 2, and a titanium metal precipitation unit has a structure in FIG. 3. The magnesium evaporation unit is provided with a graphite crucible 2 in which solid magnesium is placed and is structured to melt and evaporate the solid magnesium placed in the graphite crucible using a DC plasma torch 4 having a maximum power of 50 kW as a thermal source for evaporation.

In order to continuously collect titanium, the titanium metal precipitation unit is provided with a roll-shaped precipitation substrate 13 made of titanium and a scraper made of molybdenum for scraping away titanium deposited and grown on a surface of the precipitation substrate, as shown in FIG. 4. Note that the roll-shaped precipitation substrate 13, which is rotated by a motor, has raised and recessed sections to increase the surface area and is arranged such that a mixed gas contacts the surface of the substrate. A discharge unit is connected to the titanium metal precipitation unit. Induction-heating coils 6 are positioned on circumference of a first flow path. Induction-heating coils 10 are located on circumference of a second flow path. Induction-heating coils 11 are provided on circumference of a mixed gas unit. The coils 6, 10, 11 controlled a temperature of the respective units through induction-heating.

The DC plasma torch in the magnesium evaporation unit generated plasma flame under conditions of a power of 20 kW and a plasma gas with Ar:He being 60 slpm (average liter per minute): 10 slpm, and evaporated solid magnesium placed in the graphite crucible. Titanium tetrachloride was supplied at 20 ml/min (milliliter per minute) in a liquid phase and magnesium was supplied at 9.7 g/min. Titanium tetrachloride and magnesium were supplied to the gas mixing unit from the respective flow paths, and the mixed gas was supplied to the titanium metal precipitation unit for 12 minutes. Consequently, dendrite crystals of titanium metal were grown on the precipitation substrate. In this example, power of induction-heating coil 11 was 14.7 kW and a circumferential temperature of the gas mixing unit was controlled at 1700° C. It is assumed from a temperature gradient that a temperature in the gas mixing unit should have been 1600° C. or higher. An internal pressure of the gas mixing unit was 105 kPa. A temperature of the precipitation substrate in the titanium metal precipitation unit was controlled at 950 to 1050° C. and a pressure was controlled at 105 kPa.

### INDUSTRIAL APPLICABILITY

The process according to the invention can continuously produce titanium and the produced titanium metal is suitable for a material for melting or a powder metallurgy. The process may be also applied to applications where an ingot is necessary, such as electronic materials, aircraft parts, or power and chemical plants.

Embodiments of the process for producing titanium metal according to the invention are explained above. However, the invention is not limited thereto, and may be modified without departing from the spirit and scope of the present invention as defined in the appended claims.

### REFERENCE SIGNS LIST

1 magnesium evaporation unit
2 crucible
3 heater
4 DC plasma torch
5 first flow path
6 heater
7 second flow path
8 gas mixing unit
9 titanium metal precipitation unit
10, 11, 12 heater
13 precipitation substrate
14 scraper
15 collector
16 discharge unit

1. An apparatus for producing titanium metal, comprising:
(a) a magnesium evaporation unit for evaporating solid magnesium and a first flow path connected to the magnesium evaporation unit and for supplying gaseous magnesium;
(b) a second flow path for supplying gaseous titanium tetrachloride;
(c) a gas mixing unit in communication with the first flow path and the second flow path, wherein the gaseous magnesium and the gaseous titanium tetrachloride are mixed in the gas mixing unit, and the gas mixing unit is controlled to have an absolute pressure of 50 to 500 kPa and a temperature of not lower than 1600° C. therein;
(d) a titanium metal precipitation unit in communication with the gas mixing unit, wherein the titanium metal precipitation unit includes a precipitation substrate arranged therein, at least a part of the precipitation substrate being in a temperature range from 715 to 1500° C., an absolute pressure in the titanium metal precipitation unit being 50 to 500 kPa; and
(e) a mixed gas discharge unit in communication with the titanium metal precipitation unit.

2. The apparatus according to claim 1, wherein the magnesium evaporation unit is provided with a DC plasma torch as a thermal source for evaporating solid magnesium.

3. The apparatus according to claim 1, wherein the absolute pressure in the titanium metal precipitation unit is 90 to 200 kPa.

4. The apparatus according to claim 1, wherein at least one of the first flow path, the second flow path, the gas mixing unit, and the titanium metal precipitation unit has a graphite wall.

5. The apparatus according to claim 4, wherein a part or whole of the graphite wall is heated through induction-heating.

6. The apparatus according to claim 1, wherein the precipitation substrate is rotatable about a central axis and has a roll shape including raised and recessed sections having different diameters in a direction perpendicular to the rotation axis, and
wherein the precipitation substrate further includes a scraper for scraping away titanium metal deposited on a surface of the precipitation substrate.

7. The apparatus according to claim 1, wherein at least a part of the precipitation substrate is in a temperature range from 900 to 1200° C.

8. The apparatus according to claim 1, wherein the precipitation substrate is made of titanium or a titanium alloy.

9. A process for producing titanium metal, comprising steps of:
(a) evaporating solid magnesium;
(b) supplying gaseous magnesium evaporated in the step (a) and gaseous titanium tetrachloride into a mixing space at an absolute pressure of 50 to 500 kPa and a temperature of not lower than 1600° C. to form a mixed gas;
(c) introducing the mixed gas into a titanium metal precipitation space, the titanium metal precipitation space having an absolute pressure of 50 to 500 kPa, the titanium metal precipitation space including a precipitation substrate arranged therein, and at least a part of the precipitation substrate being in a temperature range from 715 to 1500° C.;
(d) depositing and growing titanium metal on the precipitation substrate; and
(e) discharging the mixed gas after the step (d).
